(19) United States
(12) Patent Application Publication
(10) Pub. No.: US 2026/0059777 A1
(43) Pub. Date: Feb. 26, 2026

(54) DIODE DEVICE AND METHOD FOR MANUFACTURING THE SAME

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: Tsung-Yi HUANG, Hsinchu County (TW); LinChun GUI, Shanghai City (CN); Xuepeng LI, Shanghai City (CN); Lianjie LI, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/824,605

(22) Filed: Sep. 4, 2024

(30) Foreign Application Priority Data
Aug. 22, 2024 (CN) 202411164738.1

(51) Int. Cl. H01L 29/872; H01L 21/265; H01L 21/762; H01L 29/06; H01L 29/49; H01L 29/66

(52) U.S. Cl. CPC H10D 8/60; H01L 21/26506; H01L 21/76224; H10D 8/051; H10D 62/124; H10D 64/668

(57) ABSTRACT

A diode device includes a semiconductor substrate, isolation structures, and metal silicide layers. The semiconductor substrate includes a well region and first to third doped regions in the well region. The first and second doped regions have opposite conductivity types, and a conductivity type of the well region is the same as the conductivity type of the second doped region. The third doped region is between the first and second doped regions. A conductivity type of the third doped region is the same as the conductivity type of the first doped region, and a dopant concentration of the third doped region is greater than a dopant concentration of the first doped region. The isolation structures are in the semiconductor substrate and spacing the first to third doped regions apart from each other. The metal silicide layers are respectively over the first and second doped regions.

### PRIORITY CLAIM AND CROSS-REFERENCE

This application claims priority to China Application Serial Number 202411164738.1, filed Aug. 22, 2024, which is herein incorporated by reference.

### BACKGROUND

Integrated circuit (IC) technologies are constantly being improved. Such improvements frequently involve scaling down device geometries to achieve lower fabrication costs, higher device integration density, higher speeds, and better performance. Along with the advantages from geometry size reductions, improvements to IC devices are being made. One such IC device is a Schottky barrier diode. The Schottky barrier diode comprises a metal in contact with the surface of a semiconductor material. Schottky barrier diodes exhibit very low forward voltage drop, switching speeds that approach zero time, and are particularly useful in radio-frequency applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing a diode device according to some embodiments of the present disclosure.

FIGS. 2A-8B illustrate a diode device at various stages of manufacture in accordance with some embodiments of the present disclosure.

FIG. 9 is a diagram showing breakdown voltages of diode devices in accordance with some embodiments of the present disclosure.

FIG. 10 is a circuit diagram of a direct current (DC) to DC converter.

FIG. 11A is a schematic top view of a diode device in accordance with some embodiments of the present disclosure.

FIG. 11B is a schematic cross-sectional view taken along line Y-Y of FIG. 11A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

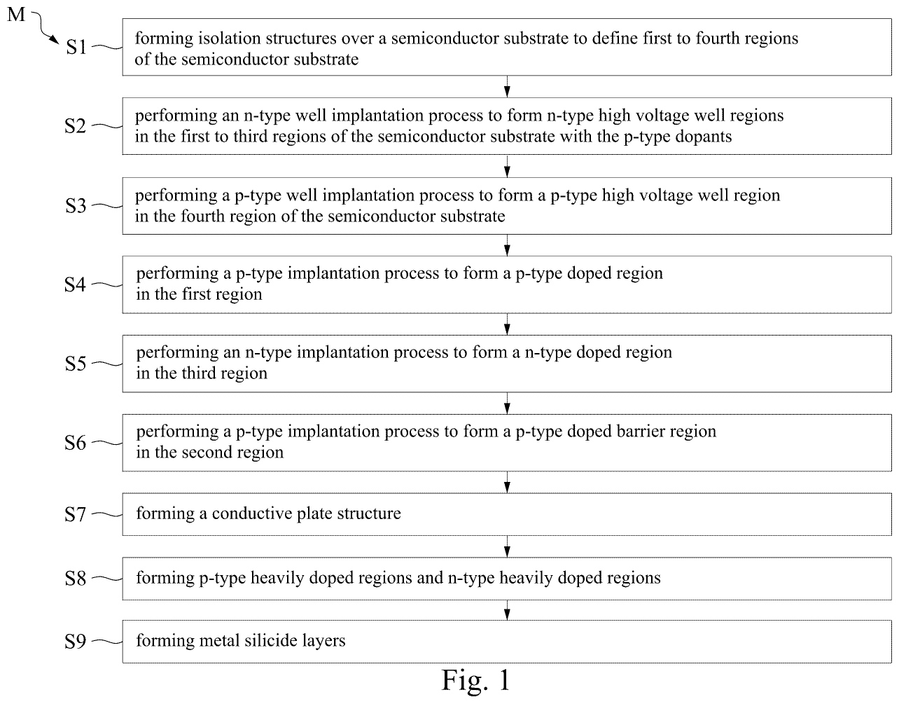

FIG. 1 is a flow chart of a method for manufacturing a diode device according to some embodiments of the present disclosure. The method M may include steps S1-S9. At step S1, isolation structures are formed over a semiconductor substrate to define first to fourth regions of the semiconductor substrate. At step S2, an n-type well implantation process is performed to form n-type high voltage well regions in the first to third regions of the semiconductor substrate with the p-type dopants. At step S3, a p-type well implantation process is performed to form a p-type high voltage well region in the fourth region of the semiconductor substrate. At step S4, a p-type implantation process is performed to form a p-type doped region in the first region. At step S5, an n-type implantation process is performed to form a n-type doped region in the third region. At step S6, a p-type implantation process is performed to form a p-type doped barrier region in the second region. At step S7, a conductive plate structure is formed. At step S8, p-type heavily doped regions and n-type heavily doped regions are formed. At step S9, metal silicide layers are formed. It is understood that additional steps may be provided before, during, and after the steps S1-S9 shown in FIG. 1, and some of the steps described below can be replaced or eliminated for additional embodiments of the method. The order of the operations/processes may be interchangeable.

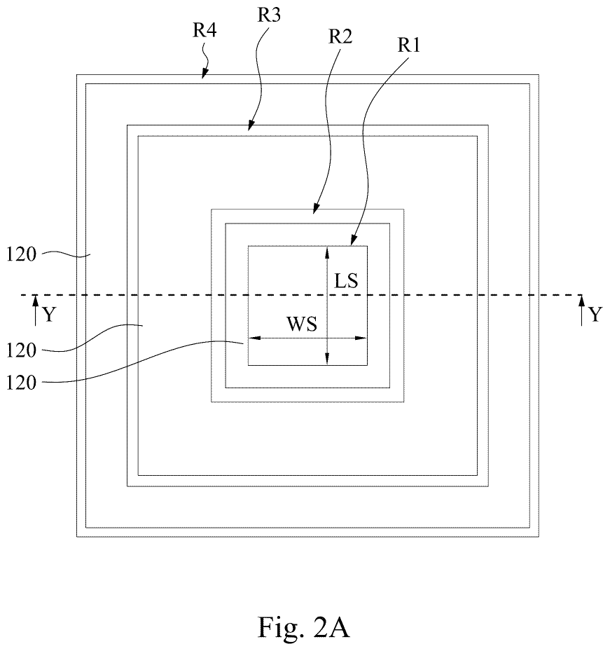

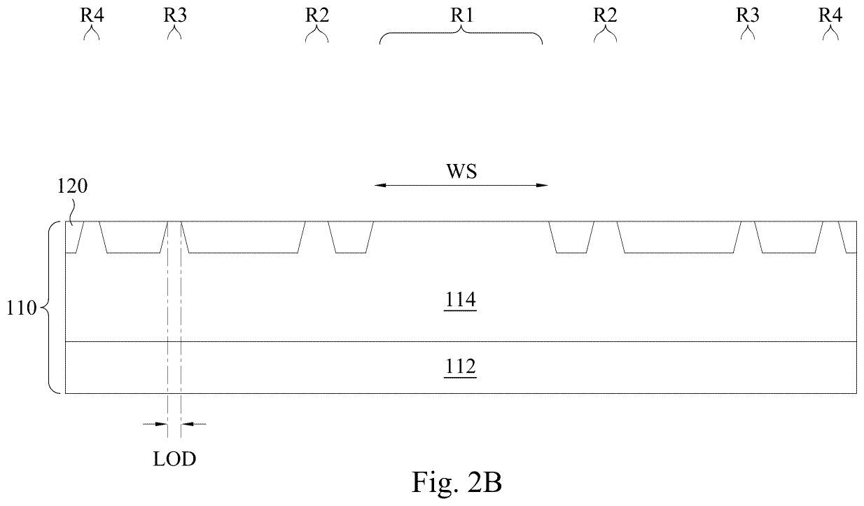

FIGS. 2A-8B illustrate a diode device at various stages of manufacture in accordance with some embodiments of the present disclosure. FIGS. 2A, 3A, 4A, 5A, 6A, and 8A are schematic top views of the diode device at various manufacturing stages in accordance with some embodiments. FIGS. 2B, 3B, 4B, 5B, 6B, 7, and 8B, are schematic cross-sectional views of the integrated circuit device (e.g., taken along line Y-Y in FIGS. 2A, 3A, 4A, 5A, 6A, and 8A) at various manufacturing stages in accordance with some embodiments. It is understood that additional operations may be provided before, during, and after the operations shown by FIGS. 2A-8B, and some of the operations described below can be replaced or eliminated for additional embodiments of the method. The order of the operations/processes may be interchangeable.

Reference is made to FIG. 1 and FIGS. 2A and 2B. The method M begins at step S1, where plural isolation structures 120 are formed over a semiconductor substrate 110. The semiconductor substrate 110 may include a base substrate 112. The base substrate 112 may be a bulk substrate, such as a bulk silicon substrate. The semiconductor substrate 110 may optionally include a semiconductor layer 114 epitaxially grown over the base substrate 112. The semiconductor layer 114 may include an elementary semiconductor, such as silicon (Si) in a crystalline structure, germanium (Ge) in a crystalline structure, a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb), or combinations thereof. In some embodiments, the base substrate 112 is a p-type substrate, and the semiconductor layer 114 is a p-type semiconductor layer.

The isolation structures 120 may define plural regions R1-R4 of the substrate 110, which may be referred to as oxide-defined regions. As shown in FIG. 2A, the regions R2-R4 are ring-shaped regions, in which the region R2 surrounds the region R1, the region R3 surrounds the region R2, and the region R4 surrounds the region R3. In some embodiments, a width WS of the region R1 may be greater than a width LOD of each of the regions R2-R4. For example, the widths LOD of the regions R2-R4 may be in a range from about 0.5 micrometers to about 2 micrometers, and the width WS and the length LS of the region R1 may be in a range from about 15 micrometers to about 20 micrometers. In some embodiments, the isolation structures 120 are made of silicon oxide, silicon nitride, silicon oxynitride, fluoride-doped silicate glass (FSG), or other low-K dielectric materials. For example, the semiconductor substrate 110 are patterned by a suitable etching process to form trenches therein, and a dielectric material may overfill the trenches. A chemical mechanical polish (CMP) process may then be performed to remove the excess dielectric material external to the trenches, thereby forming the isolation structures 120. In some embodiments, the CMP process is performed such that the isolation structures 120 are substantially level the top surface of the substrate 110.

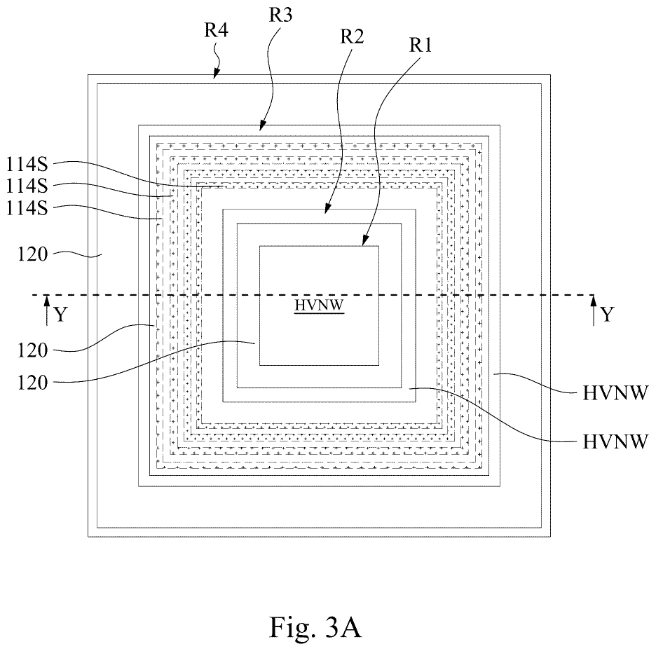

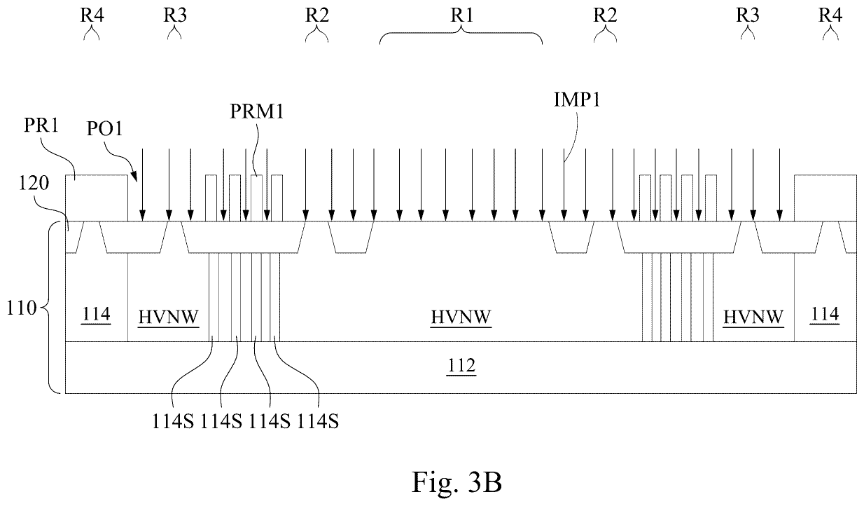

Reference is made to FIG. 1 and FIGS. 3A and 3B. The method M proceeds to step S2, where an n-type well implantation process IMP1 is performed to dope the regions R1-R3 of the semiconductor layer 114, thereby forming one or more n-type high voltage well regions HVNW in the regions R1-R3. Prior to the well implantation process IMP1, a patterned mask PR1 is formed over the isolation structures 120 and the substrate 110. In some embodiments, the patterned mask PR1 may be a photoresist mask formed by a photolithography process. For example, the photolithography process may include spin-on coating a photoresist layer over the isolation structures 120 and the substrate 110, exposing the photoresist layer to patterned light, performing a post-exposure bake process, and developing the photoresist layer to form the patterned mask PR1. In some alternative embodiments, the patterned mask PR1 may be a tri-layer resist layer, for example, including a bottom layer (e.g., CₓH_{y}O_{z}), a middle layer (e.g., SiCₓH_{y}O_{z}), and a photoresist top layer. The patterned mask PR1 may cover the entire region R4 and portions of the isolation structure 120. For example, the patterned mask PR1 may have plural mask strips PRM1 over the isolation structure 120 between the regions R2 and R3. In some embodiments, the patterned mask PR1 has an opening PO1 exposing the regions R1-R3 and some other portions of the isolation structure 120 between the regions R2 and R3.

The n-type well implantation process IMP1 may be an ion implantation process performed with n-type dopants, such as phosphorus, antimony, or arsenic. In some embodiments, a doping dose of the well implantation process IMP1 for the n-type high voltage well region HVNW is in a range from about 1×10¹²/cm² to about 1×10¹³/cm², with an energy in a range from about 50 KeV to about 3000 KeV. By controlling the ion implantation energy, the dopants may penetrate through the top surface of the semiconductor substrate 110, and the depth of the n-type high voltage well region HVNW may be adjusted accordingly. The n-type high voltage well regions HVNW may also be referred to as N-drift regions in the context.

With the masking of the mask strips PRM1, portions of the semiconductor layer 114 may be substantially free from the dopants of the n-type high voltage well regions HVNW. These portions of the semiconductor layer may be referred to as semiconductor strips 114S, which may be substantially intrinsic semiconductor regions. The term “substantially intrinsic region” means a region in a single crystalline semiconductor (e.g., silicon germanium or silicon) without intentionally doped and thus has no or negligible impurity elements, as compared to surrounding structures, such as the n-type high voltage well regions HVNW. The semiconductor strips 114S may reduce a dopant concentration of the n-type high voltage well regions HVNW between the regions R2 and R3, thereby making the electric field distribution more uniform for sustaining higher reverse voltage. The number of the semiconductor strips 114S may be in a range from 2 to 10. For example, the four semiconductor strips 114S are illustrated. If the number of the semiconductor strips 114S is less than 2, the dopant concentration of the n-type high voltage well regions HVNW may be reduced unevenly, resulting in uneven electric field distribution. If the number of the semiconductor strips 114S is greater than 10, a length of the current path may be increased unnecessarily. In some embodiments, the semiconductor strips 114S may be referred to as semiconductor slots. The semiconductor strips 114S are ring-shaped regions surrounding the regions R1 and R2, as shown in FIG. 3A. In FIG. 3A, as being covered by the isolation structures 120, the semiconductor strips 114S are depicted as having dashed-line sidewalls. The semiconductor strips 114S can be formed with the formation of the n-type high voltage well regions HVNW, and no extra mask is needed.

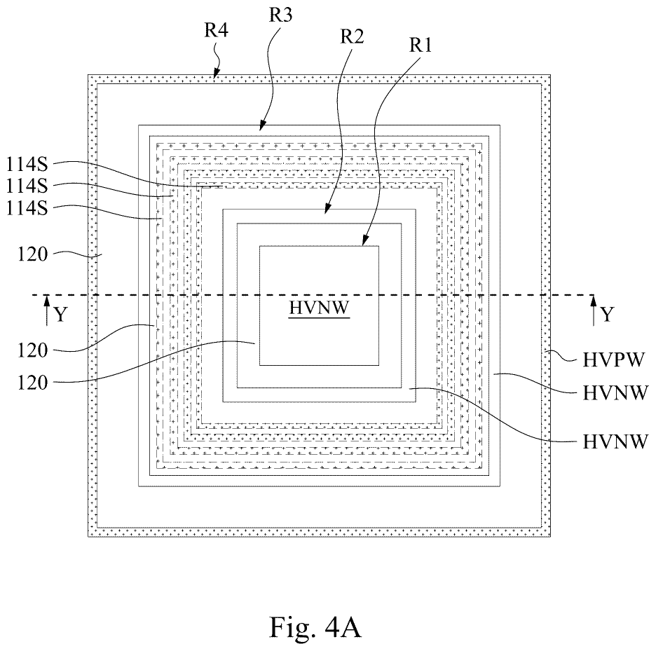

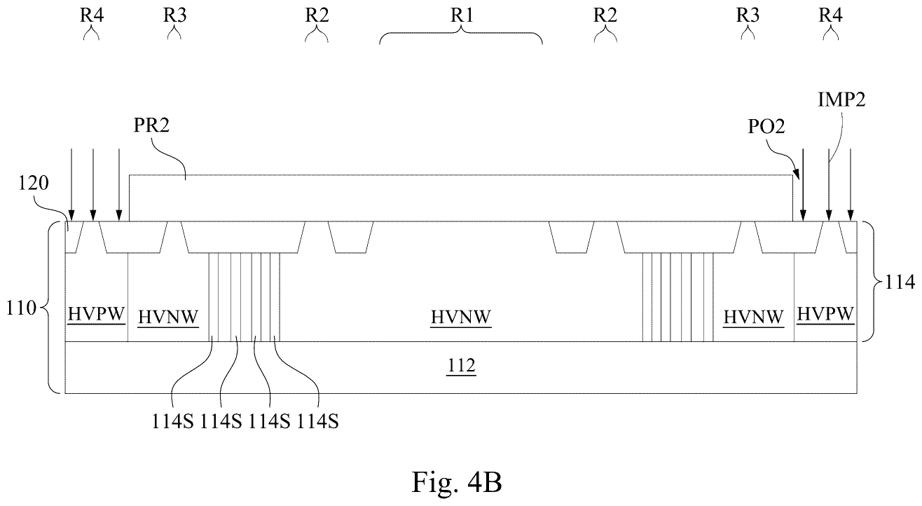

Reference is made to FIG. 1 and FIGS. 4A and 4B. The method M proceeds to step S3, where a p-type well implantation process IMP2 is performed to dope the region R4 of the semiconductor layer 114, thereby forming a p-type high voltage well regions HVPW in the region R4. Prior to the well implantation process IMP2, a patterned mask PR2 is formed over the isolation structures 120 and the substrate 110. In some embodiments, the patterned mask PR2 may be a photoresist mask formed by a photolithography process. For example, the photolithography process may include spin-on coating a photoresist layer over the isolation structures 120 and the substrate 110, exposing the photoresist layer to patterned light, performing a post-exposure bake process, and developing the photoresist layer to form the patterned mask PR2. In some alternative embodiments, the patterned mask PR2 may be a tri-layer resist layer, for example, including a bottom layer (e.g., CₓH_{y}O_{z}), a middle layer (e.g., SiCₓH_{y}O_{z}), and a photoresist top layer. The patterned mask PR2 may cover the entire regions R1-R3. In some embodiments, the patterned mask PR2 has an opening PO2 exposing the region R4.

The p-type well implantation process IMP2 may be an ion implantation process performed with p-type dopants, such as boron or BF₂, depending on design requirements. In some embodiments, a doping dose of the well implantation process IMP2 for the p-type high voltage well region HVPW is in a range from about 1×10¹²/cm² to about 1×10¹³/cm², with an energy in a range from about 50 KeV to about 3000 KeV. By controlling the ion implantation energy, the dopants may penetrate through the top surface of the semiconductor substrate 110, and the depth of the p-type high voltage well region HVPW may be adjusted accordingly.

After the implantation processes of the high voltage well regions HVNW and HVPW, a dopant drive-in processes may be performed to effectuate the diffusion of the n-type dopants and p-type dopants to the desired depth. The dopant drive-in processes may include one or more anneal steps which can be performed in a single equipment or multiple pieces of equipment. In some embodiments, the drive-in anneal is a thermal drive-in performed in a furnace. The drive-in anneal may also comprise a plurality of anneal treatments that are carried out at different points in the fabrication process.

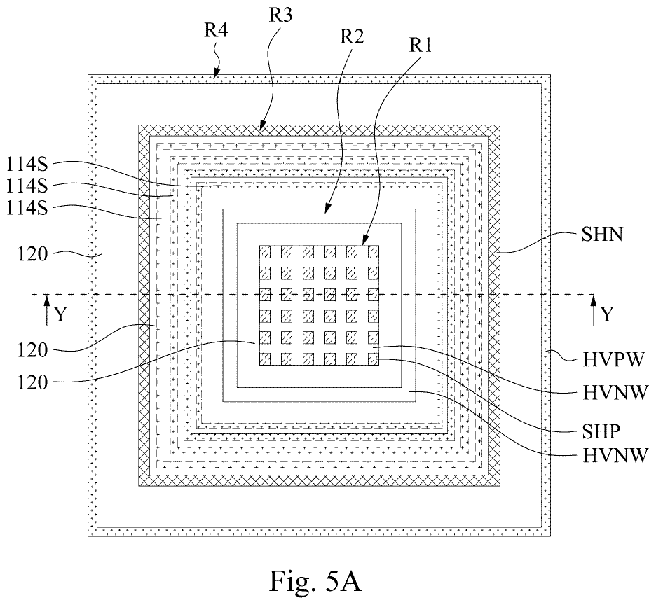

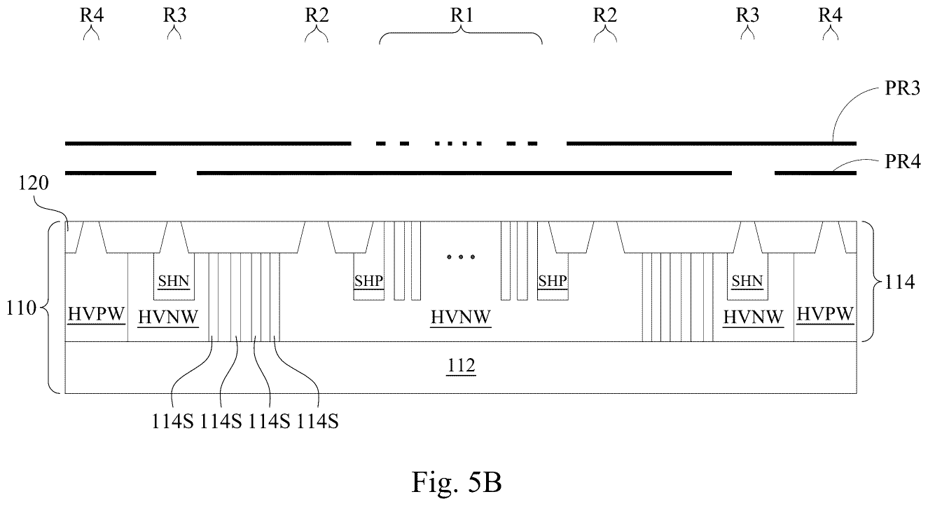

Reference is made to FIG. 1 and FIGS. 5A and 5B. The method M proceeds to step S4, where a p-type implantation process is performed to dope the region R1, thereby forming one or more p-type doped regions SHP in the high voltage well regions HVNW in the region R1. The p-type doped regions SHP are islands spaced apart from each other. The p-type doped regions SHP may be rectangular, circular, or some other shapes when viewed from top. The p-type implantation process may be an ion implantation process performed with p-type dopants, such as boron or BF₂, depending on design requirements. In some embodiments, a doping dose of the implantation process for the p-type dope regions SHP is in a range from about 1×10¹³/cm² to about 5×10¹³/cm², with an energy in a range from about 50 KeV to about 300 KeV. By controlling the ion implantation energy, the dopants may penetrate through the top surface of the semiconductor substrate 110, and the depth of the p-type dope regions SHP may be adjusted accordingly.

In some embodiments, prior to the implantation process to form the p-type doped regions SHP, a patterned implantation mask PR3 is formed over the isolation structures 120 and the substrate 110 for defining regions of the p-type doped regions SHP. For example, the patterned implantation mask PR3 may cover the regions R2-R4 and portions of the region R1, and exposing the other portions of the regions R1. The patterned implantation mask PR3 may be a photoresist mask formed by a photolithography process. The ion implantation process to form the p-type doped regions SHP may be performed with the presence of the patterned implantation mask PR3. The patterned implantation mask PR3 may be removed, for example, by suitable stripping process, after the formation of the p-type doped regions SHP. The patterned implantation mask PR3 is depicted in a simplified manner in FIG. 5B.

The method M proceeds to step S5, where an n-type implantation process is performed to dope the region R3, thereby forming one or more n-type dope regions SHN in the high voltage well regions HVNW in the region R3. The p-type doped regions SHP are surrounded by the n-type dope regions SHN. The n-type implantation process may be ion implantation process performed with n-type dopants, such as phosphorus, antimony, or arsenic. In some embodiments, a doping dose of the implantation process for the n-type dope regions SHN is in a range from about 1×10¹³/cm² to about 5×10¹³/cm², with an energy in a range from about 50 KeV to about 300 KeV. By controlling the ion implantation energy, the dopants may penetrate through the top surface of the semiconductor substrate 110, and the depth of the n-type dope region SHN may be adjusted accordingly. The step S5 may be performed before or after the step S4.

In some embodiments, prior to the implantation process to form the n-type doped region SHN, a patterned implantation mask PR4 is formed over the isolation structures 120 and the substrate 110 for defining regions of the n-type dope regions SHN. For example, the patterned implantation mask PR4 may cover the regions R1, R2, and R4, and exposing the region R3. The patterned implantation mask PR4 may be a photoresist mask formed by a photolithography process. The ion implantation process to form the n-type doped region SHN may be performed with the presence of the patterned implantation mask PR4. The patterned implantation mask PR4 may be removed, for example, by suitable stripping process, after the formation of the n-type doped region SHN. The patterned implantation mask PR4 is depicted in a simplified manner in FIG. 5B.

In some embodiments, a distance between the p-type dope regions SHP and a first one of the semiconductor strips 114S nearest to the p-type dope regions SHP is greater than a distance between the n-type dope region SHN and a second one of the semiconductor strips 114S nearest to the n-type dope region SHN. In some embodiments, bottoms of the semiconductor strips 114S are lower than a bottom of the n-type dope region SHN and bottoms of the p-type dope regions SHP.

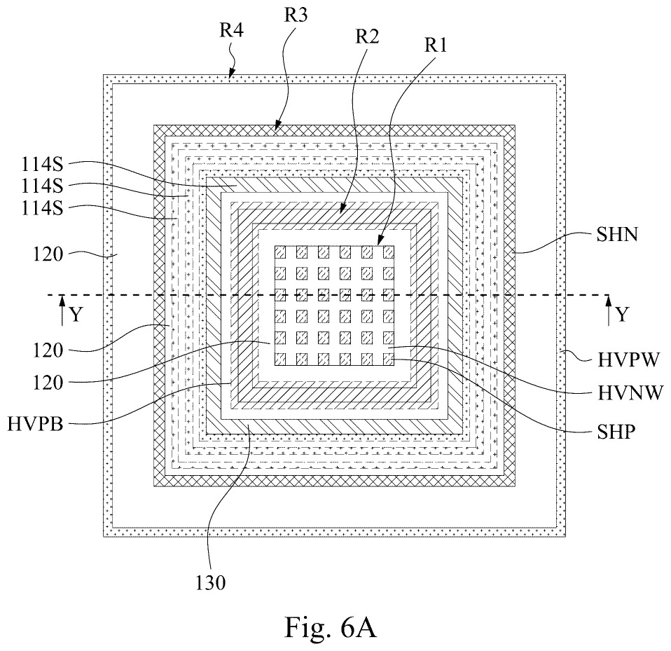

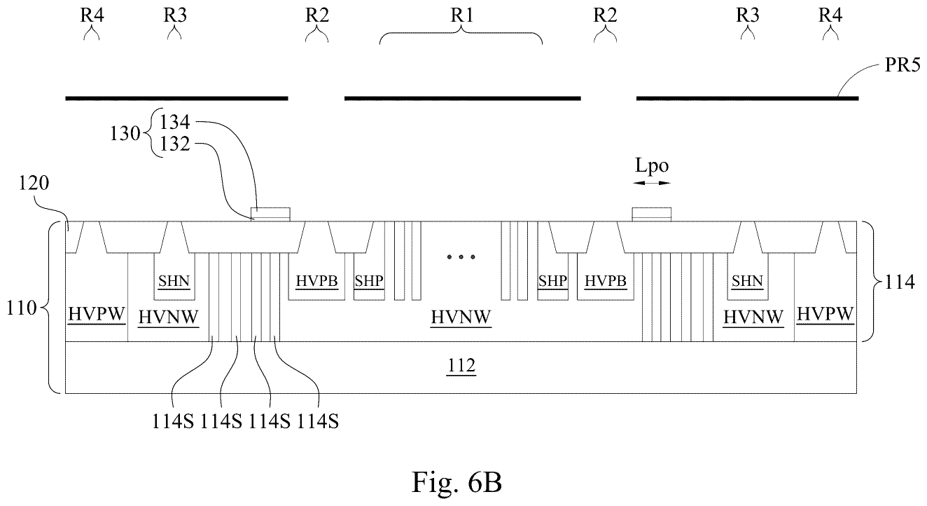

Reference is made to FIG. 1 and FIGS. 6A and 6B. The method M proceeds to step S6, where a p-type implantation process is performed to dope the region R2, thereby forming a p-type doped region HVPB in the high voltage well regions HVNW in the region R2. The p-type doped region HVPB may be referred to as a p-type doped barrier region in the context. The p-type implantation process may be an ion implantation process performed with p-type dopants, such as boron or BF₂, depending on design requirements. In some embodiments, a doping dose of the implantation process for the p-type doped region HVPB is in a range from about 1×10 ¹³/cm² to about 1×10¹⁴/cm², with an energy in a range from about 30 KeV to about 300 KeV. By controlling the ion implantation energy, the dopants may penetrate through the top surface of the semiconductor substrate 110, and the depth of the p-type doped region HVPB may be adjusted accordingly. As shown in FIG. 6A, the p-type doped region HVPB is a ring-shaped region between the n-type dope region SHN and the p-type doped regions SHP. The plate electrode 134 is near the junction edge between the p-type doped region HVPB and the high voltage well regions HVNW, and can be used to modulate the junction edge electrical field.

In some embodiments, prior to the implantation process to form the p-type doped region HVPB, a patterned implantation mask PR5 is formed over the isolation structures 120 and the substrate 110 for defining regions of the p-type doped region HVPB. For example, the patterned implantation mask PR5 may cover the regions R1, R3, and R4, and exposing the region R2. The patterned implantation mask PR5 may be a photoresist mask formed by a photolithography process. The ion implantation process to form the p-type doped region HVPB may be performed with the presence of the patterned implantation mask PR5. The patterned implantation mask PR5 may be removed, for example, by suitable stripping process, after the formation of the p-type doped region HVPB. The patterned implantation mask PR5 is depicted in a simplified manner in FIG. 6B.

Prior to or after step S6, the method M proceeds to step S7, where a conductive plate structure 130 is formed over the isolation structure 120 between the regions R2 and R3. Formation of the conductive plate structure 130 may include depositing a dielectric layer over the substrate 110 and the isolation structure 120, depositing a plate electrode layer over the gate dielectric layer, and patterning the plate electrode layer and the dielectric layer respectively into a plate electrode 134 and a dielectric 132. The dielectric layer may be formed of a suitable dielectric material such as silicon oxide, silicon oxynitride, silicon nitride, an oxide, a nitrogen-containing oxide, aluminum oxide, lanthanum oxide, hafnium oxide, zirconium oxide, hafnium oxynitride, combinations thereof and/or the like. In some embodiments, the dielectric layer may be formed by a thermal oxidation process, a CVD process, other suitable deposition processes, or the combinations thereof as well. The plate electrode layer may include a conductive material, such as doped poly-crystalline silicon, a metal (e.g., tantalum, titanium, molybdenum, tungsten, platinum, aluminum, hafnium, ruthenium), a metal nitride (e.g., titanium nitride, tantalum nitride), other conductive materials, combinations thereof and/or the like. In some embodiments where the plate electrode layer includes poly-silicon, the plate electrode layer may be formed by depositing doped or undoped poly-silicon by chemical vapor deposition (CVD). In some embodiments, a length of the conductive plate structure 130 is in a range from about 1 micrometer to about 5 micrometers. If the length of the conductive plate structure 130 is less than 1 micrometer or greater than the 5 micrometers, the conductive plate structure 130 may not modulate the junction edge electrical field effectively. In some embodiments, a thickness of the plate electrode 134 may be in a range from about 0.1 micrometer to about 0.3 micrometer. A thickness of the dielectric 132 may be in a range from about 100 Å to about 500 Å. If the thicknesses of the plate electrode 134 and the dielectric 132 is out of the ranges, the conductive plate structure 130 may not modulate the junction edge electrical field effectively.

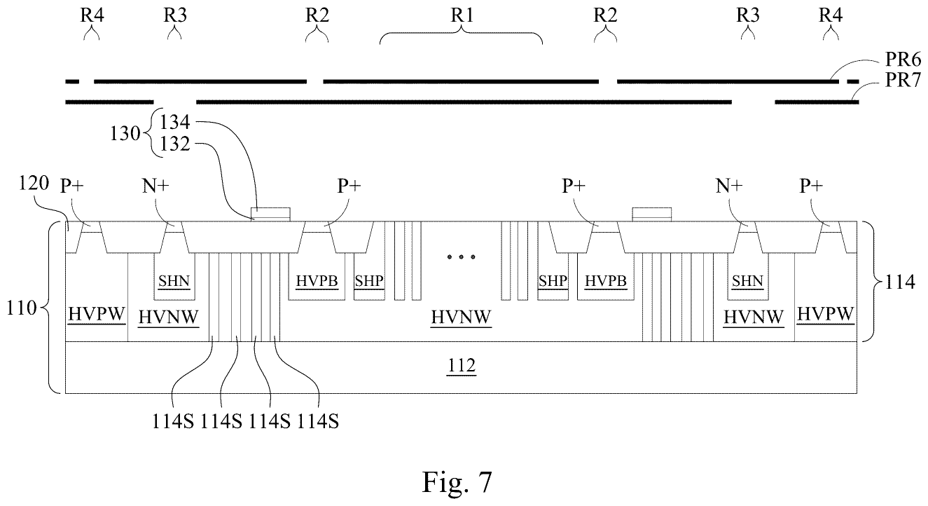

Reference is made to FIG. 1 and FIG. 7. The method M proceeds to step S8, where p-type heavily doped regions P+ and n-type heavily doped regions N+ are formed. P-type heavily doped regions P+ are formed in the p-type doped region HVPB and the p-type high voltage well regions HVPW through suitable semiconductor doping techniques such as an ion implantation process in some embodiments. And, prior to or after the formation of the p-type heavily doped regions P+, n-type heavily doped regions N+ are formed in the n-type dope region SHN through suitable semiconductor doping techniques such as an ion implantation process in some embodiments. The implantation process for the p-type heavily doped regions P+ may be performed with p-type dopants, such as boron or BF₂, depending on design requirements. The implantation process for the n-type heavily doped regions N+ may be performed with n-type dopants, such as phosphorus, antimony, or arsenic. In some embodiments, doping doses of the implantation process for the p-type heavily doped regions P+ and the n-type heavily doped regions N+ may be in a range from about 1×10¹⁴/cm² to about 1×10¹⁵/cm², with an energy in a range from about 10 KeV to about 50 KeV. By controlling the ion implantation energy, the dopants may penetrate through the top surface of the semiconductor substrate 110, and the depth of the p-type heavily doped regions P+ and the n-type heavily doped regions N+ may be adjusted accordingly. In the context, the heavily doped regions N+ and P+ may also referred to as contact doped regions.

In some embodiments, prior to the implantation process to form the p-type heavily doped regions P+, a patterned implantation mask PR6 is formed over the isolation structures 120 and the substrate 110 for defining regions of the p-type heavily doped regions P+. For example, the patterned implantation mask PR6 may cover the regions R1 and R3, and exposing the regions R2 and R4. The patterned implantation mask PR6 may be a photoresist mask formed by a photolithography process. The ion implantation process to form the p-type heavily doped regions P+ may be performed with the presence of the patterned implantation mask PR6. The patterned implantation mask PR6 may be removed, for example, by suitable stripping process, after the formation of the p-type heavily doped regions P+. The patterned implantation mask PR6 is depicted in a simplified manner in FIG. 7.

In some embodiments, prior to the implantation process to form the n-type heavily doped regions N+, a patterned implantation mask PR7 is formed over the isolation structures 120 and the substrate 110 for defining regions of the n-type heavily doped regions N+. For example, the patterned implantation mask PR7 may cover the regions R1, R2, R4, and exposing the region R3. The patterned implantation mask PR7 may be a photoresist mask formed by a photolithography process. The ion implantation process to form the n-type heavily doped regions N+ may be performed with the presence of the patterned implantation mask PR7. The patterned implantation mask PR7 may be removed, for example, by suitable stripping process, after the formation of the n-type heavily doped regions N+. The patterned implantation mask PR7 is depicted in a simplified manner in FIG. 7.

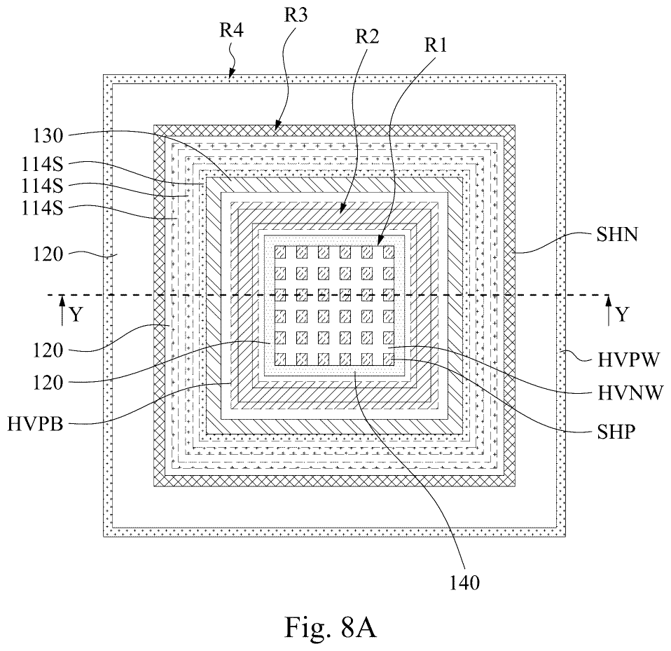

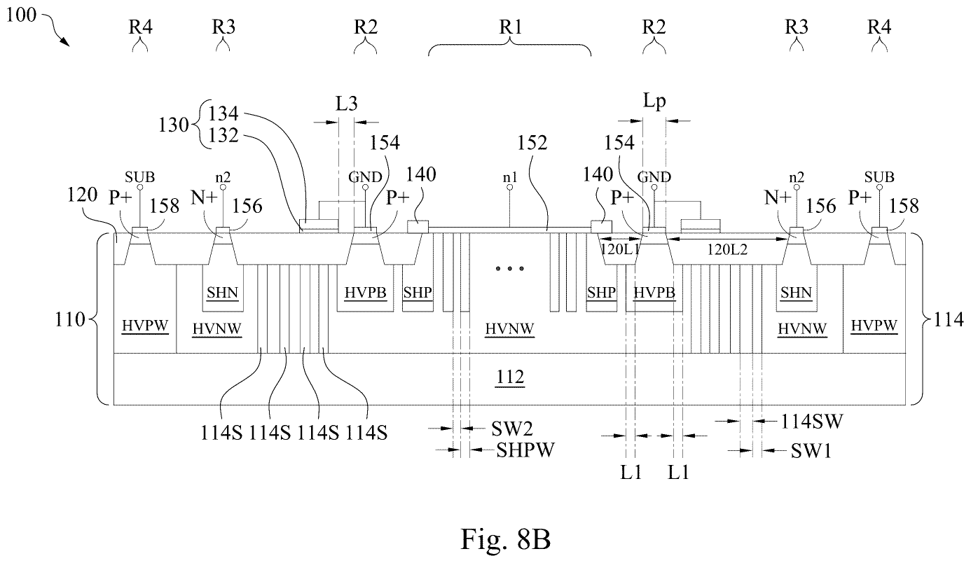

Reference is made to FIGS. 8A and 8B. The method M proceeds to step S9, where metal silicide layers 152-158 are formed. The metal silicide layer 152 is formed over the n-type high voltage well regions HVNW including the p-type doped regions SHP in the region R1. The metal silicide layer 154 is formed over the p-type heavily doped region P+ over the p-type doped barrier region HVPB in the region R2. The metal silicide layer 156 is formed over the n-type heavily doped region N+ in the region R3. And, the metal silicide layer 158 is formed over the p-type heavily doped region P+ over the p-type high voltage well regions HVPW in the region R4. The metal silicide layers 152-158 may serve as contacts. In some embodiments, the metal silicide layers 152-158 include titanium silicide, although other metal silicides, such as cobalt silicide, tantalum silicide, and combinations thereof, can be used. The metal silicide layers 152-158 may be formed using a self-aligned silicidation process, which includes depositing a metal layer (not shown) on the substrate 110, and performing an annealing process to react the metal with the underlying silicon. In some embodiments, the metal layer is fully consumed during the silicidation process. Alternatively, a layer of metal may be left un-reacted after the anneal, and removed by suitable etching/cleaning process after the silicidation process.

As the dopant concentration of the p-type doped regions SHP and the n-type high voltage well regions HVNW are less than the dopant concentration of the heavily doped regions P+ and N+ and the p-type doped region HVPB, a thickness of the metal silicide layer 152 is less than thicknesses of the metal silicide layers 154, 156, and 158. For example, the heavily doped region N+ is between the metal silicide layer 156 and the n-type doped region SHN, and the heavily doped region N+ may space the metal silicide layer 156 from the n-type doped region SHN. For example, the heavily doped region P+ is between the metal silicide layer 158 and the p-type high voltage well regions HVPW, and the heavily doped region P+ may space the metal silicide layer 158 from the p-type high voltage well regions HVPW. And, the metal silicide layer 152 is in direct contact with the p-type doped region SHP and the n-type high voltage well regions HVNW.

In some embodiments, prior to the formation of the metal silicide layers 152-158, a resist protection oxide (RPO) 140 is formed over the n-type high voltage well regions HVNW including the p-type doped regions SHP in the region R1 and one of the isolation structures 120 between the regions R1 and R2. Formation of the RPO 140 may include depositing a dielectric layer over the structure of FIG. 7, and patterning the dielectric layer into the RPO 140 to expose the underlying substrate. The dielectric layer may include an oxide layer, a nitride layer, an oxy-nitride layer, other suitable layers, and/or combinations thereof. The RPO 140 can eliminates leakage current and reduces parasitic resistance. The RPO 140 may also limit an area of the metal silicide layer 152.

Through the processes from FIGS. 2A-8B, a Schottky barrier diode (SBD) 100 is formed. Various contact/conductive features may be formed over the SBD 100, providing connections between the metal silicide layers 152-158 of the SBD 100 and the nodes n1, n2, GND, and SUB, respectively. For example, the high voltage well region HVNW including the p-type doped regions SHP is electrically connected to the node n1, through the metal silicide layer 152. The high voltage well region HVNW including the p-type doped region SHP may be electrically connected to the node n1, through the metal silicide layer 152. The p-type doped region HVPB and the p-type heavily doped regions P+ thereon may be connected to the node GND, through the metal silicide layer 154. The n-type doped region SHN and the n-type heavily doped regions N+ thereon may be electrically connected to the node n2, through the metal silicide layer 156. The high voltage well region HVPW and the p-type heavily doped regions P+ thereon may be connected to the node SUB, through the metal silicide layer 158. The node GND may be a base voltage potential, such as ground potential. The node SUB may be a biasing voltage potential, such as ground potential or other suitable voltage potential. The node n1 is a plus node of the SBD 100, while the node n2 is a minus node of the SBD 100. Under SBD forward bias operation, the node n1 is a positive voltage potential, the node n2 is a negative voltage potential. Under SBD reverse bias operation, the node n1 is a negative voltage potential, the node n2 is a positive voltage potential. By the configuration, during SBD reverse bias operation, most of the voltage pinches off between the node GND and the node n2, and the device interior part at the node n1 is protected, thereby improving the breakdown voltage. Technology computer aided design (TCAD) Simulation results may show the improvement in the breakdown voltage. In the context, the region R2 may be referred to as a ground region. The region R1 may be referred to as a p-type contact region. And, the region R3 may be referred to as a n-type contact region.

The plate electrode 134 is also connected to the base voltage potential, such as the ground potential. With the configuration, the plate electrode 134 can reduces the high electric field at a junction edge between the p-type doped region HVPB and the high voltage well regions HVNW, which eliminates the breakdown weak point.

In some embodiments, for achieving the SBD 100 with improved breakdown voltage, a dopant concentration of the p-type doped region HVPB is greater than dopant concentrations of the p-type doped regions SHP and the n-type doped region SHN, and the dopant concentrations of the p-type doped regions SHP and the n-type doped region SHN are greater than dopant concentrations of the high voltage well regions HVNW and HVPW. Dopant concentration of the p-type heavily doped regions P+ and n-type heavily doped regions N+ are greater than the dopant concentration of the p-type doped region HVPB, the dopant concentrations of the p-type doped regions SHP and the n-type doped region SHN, and the dopant concentrations of the high voltage well regions HVNW and HVPW.

In some embodiments, the isolation structure 120 between the regions R1 and R2 has a length 120L1, the isolation structure 120 between the regions R3 and R2 has a length 120L2 greater than the length 120L1. Through the configuration, the p-type doped region HVPB is closer to the p-type doped regions SHP than to the n-type doped region SHN. Stated differently, a distance between the p-type doped region HVPB and the p-type doped regions SHP is less than a distance between the p-type doped region HVPB and the n-type doped region SHN. For example, the length 120L1 may be in a range from about 2 micrometers to about 5 micrometers, and the length 120L2 may be in a range from about 5 micrometers to about 10 micrometers. If the length 120L1 is greater than about 5 micrometers, or the length 120L2 is greater than about 10 micrometers, the current path of the diode would be increased unnecessarily. If the length 120L1 is less than about 2 micrometers, or the length 120L2 is less than about 5 micrometers, the spaces between the regions R1-R3 may be too narrow, such that the doped regions in the regions R1-R3 may undesirably touch each other.

In some embodiments, the p-type doped region HVPB may have lengths L1 and L2 below the isolation structures 120. The lengths L1 and L2 may be controlled well such that the p-type doped region HVPB is spaced apart from the p-type doped regions SHP and the semiconductor strips 114S. The p-type doped region HVPB may extend beyond a sidewall of the metal silicide layer 154 by a length L3. For example, the lengths L1-L3 may be in a range from about 0.5 micrometer to about 1 micrometer. If the lengths L1-L3 are greater than about 1 micrometer, the p-type doped region HVPB may undesirably touch the p-type doped regions SHP and the semiconductor strips 114S. If the lengths L1-L3 are less than 0.5 micrometer, the p-type doped region HVPB may improve breakdown voltage effectively. In some embodiments, a length Lp of the metal silicide layer 154 may be greater than that of the lengths L1-L3. For example, the length Lp may be in a range from about 1 micrometer to about 2 micrometers.

In some embodiments, the width 114SW of the semiconductor strips 114S may be substantially equal to a space SW1 between every two adjacent semiconductor strips 114S. In some alternative embodiments, the width 114SW of the semiconductor strips 114S may be greater or less than the space SW1 between every two adjacent semiconductor strips 114S. For example, the width 114SW may be in a range from about 0.5 micrometer to about 2 micrometers. And, the space SW1 may be in a range from about 0.5 micrometer to about 2 micrometers.

In some embodiments, the width SHPW of the p-type doped regions SHP may be substantially equal to a space SW2 between every two adjacent p-type doped regions SHP. In some alternative embodiments, the width SHPW of the p-type doped regions SHP may be greater or less than the space SW2 between every two adjacent p-type doped regions SHP. For example, the width SHPW may be in a range from about 0.5 micrometer to about 1 micrometer. And, the space SW2 may be in a range from about 0.5 micrometer to about 1 micrometer. In the present embodiments, the width SHPW of the p-type doped regions SHP are less than the width 114SW of the semiconductor strips 114S, and the space SW2 is less than the space SW1. In some alternative embodiments, the width SHPW of the p-type doped regions SHP can be equal to or greater than the width 114SW of the semiconductor strips 114S, and the space SW2 can be equal to or greater than the space SW1.

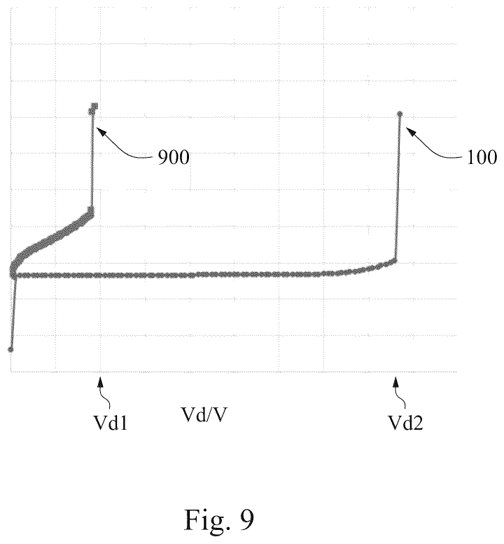

FIG. 9 is a diagram showing breakdown voltages of diode devices, SBDs 100 and 900, in accordance with some embodiments of the present disclosure. The horizonal axis represents reverse bias voltage drop (Vd), and the vertical axis represents diode current (Id). The structure of the SBD 100 is shown in FIGS. 8A and 8B. The SBD 900 is similar to the SBD 100, except that the SBD 900 does not include the conductive plate structure 130, the region R2 (e.g., the p-type doped region HVPB and the p-type heavily doped region P+ thereon), and the semiconductor strips 114S of the SBD 100 (referring to FIGS. 8A and 8B). In FIG. 9, the diode current of the SBD 900 climb fast (almost vertically) at a first voltage drop Vd1. And, the diode current of the SBD 100 climb fast (almost vertically) at a second voltage drop Vd2 much greater than the first voltage drop Vd1. The first voltage drop Vd1 may be considered as a breakdown voltage of the SBD 900, and the second voltage drop Vd2 may be considered as a breakdown voltage of the SBD 100. As evidenced from FIG. 9, by adding the conductive plate structure 130, the region R2 (e.g., the p-type doped region HVPB and the p-type heavily doped region P+ thereon), and the semiconductor strips 114S of the SBD 100 (referring to FIGS. 8A and 8B), the breakdown voltage is significantly improved, which is beneficial in the power management applications such as DC-DC converter, motor driver, the like, or other suitable devices.

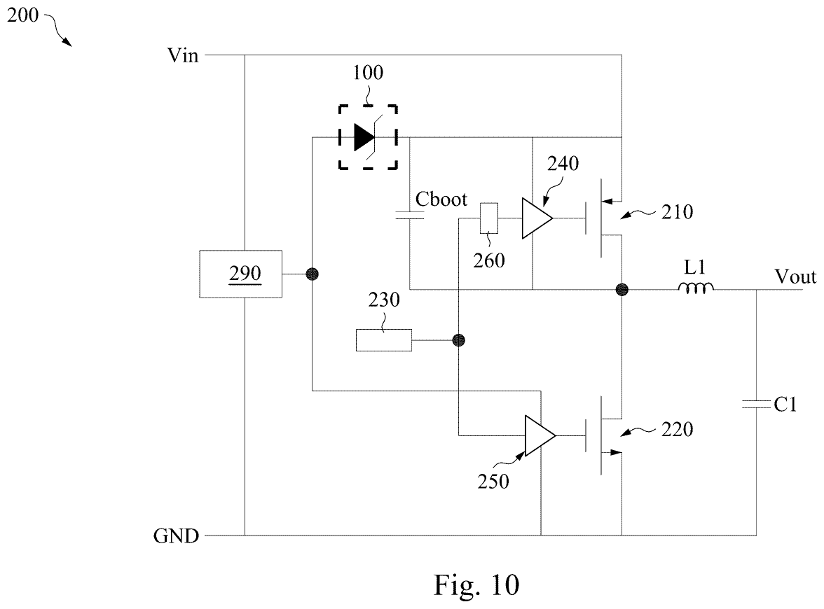

FIG. 10 is a circuit diagram of a direct current (DC) to DC converter 200. The DC to DC converter 200 may include a high-side switch 210, a low-side switch 220, a pulse-width modulation (PWM) controller 230, a high-side driver 240, a low-side driver 250, and a level-shifter 260. The high-side switch 210 is connected between the input node Vin and the output node Vout, and the low-side switch 220 is connected between the ground node GND and the output node Vout. The low-side driver 250 is connected between the PWM controller 230 and the gate of the low-side switch 220. The level-shifter 260 connects the PWM controller 230 to the gate of the high-side switch 210. The DC to DC converter 200 may further include a voltage regulator 290 connected between the input node Vin and the ground node GND. The DC to DC converter 200 may further include SBD 100 connecting between the voltage regulator 290 and the high-side switch 210. The DC to DC converter 200 may further include capacitors C1 and Cboot, an inductor L1, the like, or other suitable elements.

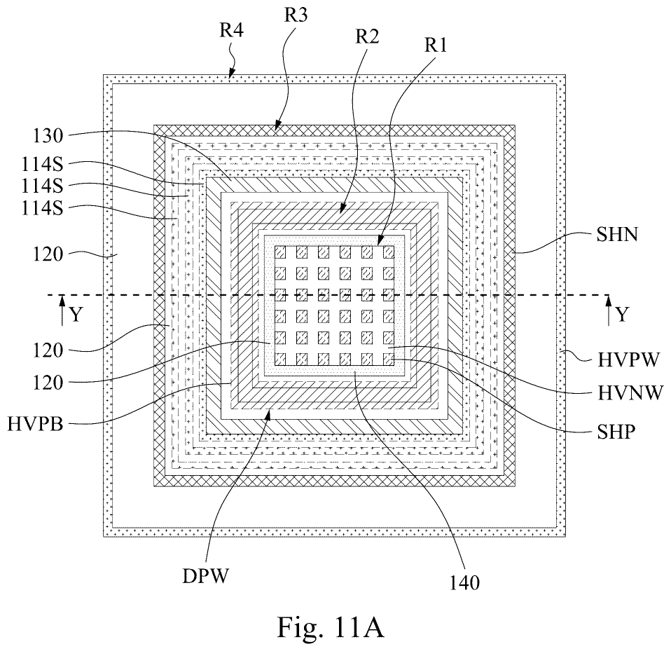

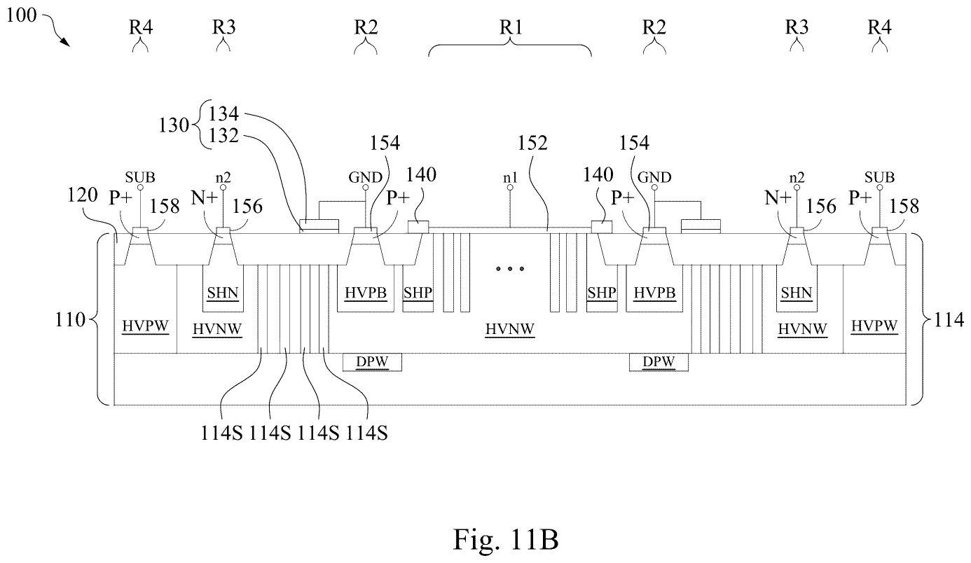

FIG. 11A is a schematic top view of a diode device in accordance with some embodiments of the present disclosure. FIG. 11B is a schematic cross-sectional view taken along line Y-Y of FIG. 11A. Details of the present embodiments are similar to those illustrated in FIGS. 2A-8B, except that the SBD 100 further include p-type deep well regions DPW below the p-type doped region HVPB. As shown in FIG. 11A, the p-type deep well regions DPW is a ring-shaped region between the n-type dope region SHN and the p-type doped regions SHP and overlapping the p-type doped region HVPB. The high voltage well regions HVNW has a portion between the p-type doped region HVPB and the p-type deep well regions DPW, thereby spacing the p-type doped region HVPB from the p-type deep well regions DPW. With the configuration of the p-type deep well regions DPW, the pinch-off effect is enhanced.

In some embodiments, a doping dose of the implantation process for the p-type deep well regions DPW is in a range from about 1×10¹²/cm² to about 1×10¹³/cm². The p-type deep well regions DPW may reduce current leakages. In some embodiments, prior to epitaxially growing the semiconductor layer 114 over the base substrate 112, regions of the base substrate 112 is doped with p-type dopants to form the p-type deep well regions DPW; and then the semiconductor layer 114 over the base substrate 112 is epitaxially growing over the base substrate 112 including the p-type deep well regions DPW. In some alternative embodiments, after the growth the semiconductor layer 114, the p-type deep well regions DPW is formed by implanting dopants with high energy, such that the dopants may penetrate the semiconductor layer 114 into the underlying base substrate 112, thereby forming the p-type deep well regions DPW.

In some embodiments, for achieving the SBD 100 with improved breakdown voltage, a dopant concentration of the p-type doped region HVPB is greater than dopant concentrations of the p-type doped regions SHP and the n-type doped region SHN, and the dopant concentrations of the p-type doped regions SHP and the n-type doped region SHN are greater than dopant concentrations of the high voltage well regions HVNW and HVPW. Dopant concentration of the p-type heavily doped regions P+ and n-type heavily doped regions N+ are greater than the dopant concentration of the p-type doped region HVPB, the dopant concentrations of the p-type doped regions SHP and the n-type doped region SHN, and the dopant concentrations of the high voltage well regions HVNW and HVPW, and a dopant concentration of the p-type deep well regions DPW.

In some embodiments, the dopant concentration of the p-type deep well regions DPW is comparable to the dopant concentration of the high voltage well region HVPW. For example, the dopant concentration of the p-type deep well regions DPW may be less than the dopant concentrations of the p-type doped regions SHP and the n-type doped region SHN. In some alternative embodiments, the dopant concentration of the p-type deep well regions DPW may be greater than that of the dopant concentrations of the p-type doped regions SHP and the n-type doped region SHN.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the breakdown voltage of the SBD at reverse bias voltage is improved by adding the ground region between the p-type contact region and the n-type contact region. Another advantage is that the breakdown voltage of the SBD at reverse bias voltage is further improved by reducing a concentration of the n-type high voltage well regions between the p-type contact region and the n-type contact region by adding the semiconductor strips. Still another advantage is that the poly plate is adjacent the junction edge, which reduces the high electric field at junction edge, which eliminates the breakdown weak point. Still another advantage is that the fabrication process is compatible with the technology. Still another advantage is that the SBD can be adopted in DC-DC Converter, Motor Driver, the like, or other suitable products.

According to some embodiments of the present disclosure, a diode device includes a semiconductor substrate, isolation structures, and first and second metal silicide layers. The semiconductor substrate includes a well region and first to third doped regions in the well region. The first and second doped regions have opposite conductivity types, and a conductivity type of the well region is the same as the conductivity type of the second doped region. The third doped region is between the first and second doped regions. A conductivity type of the third doped region is the same as the conductivity type of the first doped region, and a dopant concentration of the third doped region is greater than a dopant concentration of the first doped region. The isolation structures are in the semiconductor substrate and spacing the first to third doped regions apart from each other. The first and second metal silicide layers are respectively over the first and second doped regions.

According to some embodiments of the present disclosure, a diode device includes a semiconductor substrate, an isolation structure, and first and second metal silicide layers. The semiconductor substrate includes a well region, at least one first doped region in the well region, a second doped region, semiconductor strip regions in the well region. The first and second doped regions have opposite conductivity types, and a conductivity type of the well region is the same as the conductivity type of the second doped region, and the second doped region encircles the at least one first doped region in a top view. The semiconductor strip regions are between the first and second doped regions. A dopant concentration of the semiconductor strip regions is less than a dopant concentration of the well region. The isolation structure is in the semiconductor substrate and spacing the first doped region apart from the second doped region. The first metal silicide layer is over the first doped region. The second metal silicide layer is over the second doped region.

According to some embodiments of the present disclosure, a method for manufacturing a semiconductor device is provided. The method includes forming a plurality of isolation structures over a semiconductor substrate, wherein the isolation structures define a first region, a second region, and a third region of the semiconductor substrate, and the second region is between the first region and the third region; performing a first implantation process to dope the first region of the semiconductor substrate with a first conductivity type; performing a second implantation process to dope the third region of the semiconductor substrate with a second conductivity type opposite to the first conductivity type; and performing a third implantation process to dope the second region of the semiconductor substrate with the first conductivity type, wherein a doping dose of the third implantation process is greater than a doping dose of the first implantation process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A diode device, comprising:
a semiconductor substrate, comprising:
a well region;
a first doped region in the well region;
a second doped region in the well region, wherein the first and second doped regions have opposite conductivity types, and a conductivity type of the well region is the same as the conductivity type of the second doped region; and
a third doped region in the well region and between the first doped region and the second doped region, wherein a conductivity type of the third doped region is the same as the conductivity type of the first doped region, and a dopant concentration of the third doped region is greater than a dopant concentration of the first doped region;
a plurality of isolation structures in the semiconductor substrate and spacing the first, second and third doped regions apart from each other;
a first metal silicide layer over the first doped region; and
a second metal silicide layer over the second doped region.

2. The diode device of claim 1, wherein a distance between the third doped region and the first doped region is less than a distance between the third doped region and the second doped region.

3. The diode device of claim 1, further comprising:
a third metal silicide layer over the third doped region.

4. The diode device of claim 3, further comprising:
a plate electrode over the isolation structures and electrically connected with the third metal silicide layer.

5. The diode device of claim 3, wherein the third metal silicide layer is grounded.

6. The diode device of claim 1, wherein the second doped region surrounds the first doped region in a top view, and the third doped region surrounds the second doped region in the top view.

7. The diode device of claim 1, wherein bottoms of the first to third doped regions are lower than a bottom surface of the isolation structures.

8. The diode device of claim 1, further comprising:
a heavily doped region between the second doped region and the second metal silicide layer, and having a dopant concentration greater than a dopant concentration of the second doped region.

9. The diode device of claim 1, wherein a thickness of the first metal silicide layer is less than a thickness of the second metal silicide layer.

10. A diode device, comprising:
a semiconductor substrate, comprising:
a well region;
at least one first doped region in the well region;
a second doped region in the well region, wherein the first and second doped regions have opposite conductivity types, and a conductivity type of the well region is the same as the conductivity type of the second doped region, and the second doped region encircles the at least one first doped region in a top view; and
a plurality of semiconductor strip regions in the well region and between the first and second doped regions, wherein a dopant concentration of the semiconductor strip regions is less than a dopant concentration of the well region;
an isolation structure in the semiconductor substrate and spacing the first doped region apart from the second doped region;
a first metal silicide layer over the first doped region; and
a second metal silicide layer over the second doped region.

11. The diode device of claim 10, wherein the semiconductor strip regions are directly below the isolation structure.

12. The diode device of claim 10, wherein a distance between the first doped region and a first one of the semiconductor strip regions nearest to the first doped region is greater than a distance between the second doped region and a second one of the semiconductor strip regions nearest to the second doped region.

13. The diode device of claim 10, wherein the semiconductor strip regions are substantially intrinsic semiconductor regions.

14. The diode device of claim 10, wherein the semiconductor substrate comprises a plurality of the first doped regions in the well region, and the isolation structure spaces the first doped regions apart from the second doped region.

15. The diode device of claim 10, wherein the semiconductor strip regions surround the at least one first doped region in the top view.

16. A method for manufacturing a diode device, comprising:
forming a plurality of isolation structures over a semiconductor substrate, wherein the isolation structures define a first region, a second region, and a third region of the semiconductor substrate, and the second region is between the first region and the third region;
performing a first implantation process to dope the first region of the semiconductor substrate with a first conductivity type;
performing a second implantation process to dope the third region of the semiconductor substrate with a second conductivity type opposite to the first conductivity type; and
performing a third implantation process to dope the second region of the semiconductor substrate with the first conductivity type, wherein a doping dose of the third implantation process is greater than a doping dose of the first implantation process.

17. The method of claim 16, wherein the first conductivity type is p-type, and the second conductivity type is n-type.

18. The method of claim 17, further comprising:
prior to the first implantation process, performing a well implantation process to form a plurality of n-type well regions in the first to third regions.

19. The method of claim 16, further comprising:
forming a conductive plate structure over one of the isolation structures between the second and third regions of the semiconductor substrate.

20. The method of claim 16, further comprising:
forming a plurality of metal silicide layers over the first to third regions after the first to third implantation processes.
